(19) United States
(12) Patent Application Publication
(10) Pub. No.: US 2025/0364206 A1
(43) Pub. Date: Nov. 27, 2025

(54) METHOD AND SYSTEMS FOR BALANCING CHARGES ON A SURFACE OF AN OBJECT COMPRISING INTEGRATED CIRCUIT PATTERNS IN A SCANNING ELECTRON MICROSCOPE

(71) Applicant: Carl Zeiss SMT GmbH, Oberkochen (DE)

(72) Inventor: Thomas Korb, Schwaebisch Gmuend (DE)

(21) Appl. No.: 19/294,375

(22) Filed: Aug. 8, 2025

Related U.S. Application Data
(63) Continuation of application No. PCT/EP2024/054461, filed on Feb. 21, 2024.

(30) Foreign Application Priority Data
Mar. 3, 2023 (DE) 102023105369.8

(51) Int. Cl. H01J 37/28; H01J 37/06

(52) U.S. Cl. CPC H01J 37/28; H01J 37/06; H01J 2237/0048; H01J 2237/04

(57) ABSTRACT

The invention relates to a method for balancing charges on a surface of an object comprising integrated circuit patterns in a scanning electron microscope, the method comprising: scanning an area on the surface of the object with a first electron beam with a first landing energy one or more times to generate a scanning electron microscopy image of the area and subsequently scanning the area on the surface of the object with a second electron beam with a second landing energy one or more times such that the charges accumulated on the surface of the object are at least partially balanced. The invention also relates to scanning electron microscopes with a single or dual beam column setup for imaging and erasing the accumulated charges.

### CROSS-REFERENCE TO RELATED APPLICATIONS

This application is a continuation of and claims benefit under 35 U.S.C. § 120 from PCT application PCT/EP2024/054461, filed on Feb. 21, 2024, which claims priority to German patent application 10 2023 105 369.8, filed on Mar. 3, 2023. The entire contents of these earlier applications are herein incorporated by reference in their entirety.

### TECHNICAL FIELD

The invention relates to methods and systems for balancing positive and negative charges on a surface of an object comprising integrated circuit patterns in a scanning electron microscope. The methods and systems can be utilized for semiconductor device metrology, defect inspection or defect review of integrated circuits within objects comprising integrated circuit patterns.

### BACKGROUND

An object comprising integrated circuit patterns can refer, for example, to a photolithography mask, a reticle or a wafer. In a photolithography mask or reticle the integrated circuit patterns are mask structures used to generate semiconductor patterns in a wafer during the photolithography process. In a wafer the integrated circuit patterns are semiconductor structures, which are imprinted on the wafer during the photolithography process.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. For example, during the manufacturing of 3D-memory devices, the critical processes are currently etching and deposition. Other involved process steps such as the photolithography exposure or implantation also can have an impact on the properties of the elements of the integrated circuits. Further influences arise, for example, from degeneration of photolithography masks or particle contamination. Due to the various influences during the production process of wafers and the requirement to create ever smaller and smaller structures, various defects can occur on the wafers. Therefore, devices and methods for defect inspection and defect review in wafers are required to ensure high quality production yields. The recognized defects can, for example, serve as feedback to improve the process parameters of the manufacturing process, e.g., exposure time, focus variation, etc., or they can be used during quality control.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3rd (vertical) dimension. The current height of the memory stacks is exceeding a dozen of microns. In contrast, the feature size is becoming smaller. The minimum feature size or critical dimension is below 10 nm, for example 7 nm or 5nm, and is approaching feature sizes below 3 nm in near future. While the complexity and dimensions of the semiconductor structures are growing into the 3^{rd} dimension, the lateral dimensions of integrated semiconductor structures are becoming smaller. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter has a limited dimension, which depends on the charged particle beam operation conditions and lens. The beam resolution is limited by approximately half of the beam diameter. The lateral resolution can be below 2 nm, for example even below 1 nm. Producing the small structure dimensions imaged onto the wafer requires photolithographic masks or templates for nanoimprint photolithography with ever smaller structures or pattern elements.

The production process of photolithographic masks and templates for nanoimprint photolithography is, therefore, becoming increasingly more complex and, as a result, more time-consuming and ultimately also more expensive. On account of the tiny structure sizes of the pattern elements of photolithographic masks or templates, it is not possible to exclude errors during mask or template production. The resulting defects can, for example, arise from degeneration of photolithography masks or particle contamination. Of the various defects occurring during semiconductor structure manufacturing, photolithography related defects make up nearly half of the number of defects. Hence, in semiconductor process control, photolithography mask inspection, review, and metrology play a crucial role to monitor systematic defects. Defects detected during quality assurance processes can be used for root cause analysis, for example, to modify or repair the photolithography mask. The defects can also serve as feedback to improve the process parameters of the manufacturing process, e.g., exposure time, focus variation, etc.

In order to detect defects of ever smaller size in objects comprising integrated circuit patterns, imaging datasets of the object surface are generated and inspected for defects.

For imaging large regions of an object surface with sufficient resolution to detect small defects in a short period of time current technologies such as scanning electron microscopy (SEM) or multibeam scanning electron microscopy (multibeam SEM) can be used. Multibeam SEM uses multiple single beams in parallel, each beam covering a separate portion of a surface, with pixel sizes down to 2 nm.

A SEM scans the surface of an object comprising semiconductor patterns using an electron beam with a specified landing energy. The electrons either interact with the object and cause an emission of secondary electrons (SE) or they bounce off the object as back-scattered electrons (BSE). The secondary electrons and/or the back-scattered electrons are detected by a detector. The detector is coupled to a computer system that generates an image of the object comprising semiconductor patterns by counting the emitted electrons per dwell point. The landing energy is carefully selected to optimize the image quality (e.g., structure contrast and edge sharpness) with respect to the structures of interest. However, the number of emitted electrons will in most cases not balance the number of injected electrons such that charges remain on the surface of the object. The charge built-up on the object surface results from the difference between the incident electrons and the number of emission electrons. Especially for objects of insulative material, e.g., silicon dioxide, charges build up quickly. The term “charge built-up” in a particle beam instrument relates to the build-up of either positive or negative potential at or near the surface of an object while it is being irradiated by a particle beam.

Excess charges are undesirable for different reasons. On the one hand, the incident electron beam of the SEM interacts with the materials of the object surface leading to a potential radiation damage. On the other hand, changes in the surface potential alter the flight path of the primary electrons of the electron beam, thus affecting the image quality. For example, image distortions, contrast variations, changes in magnification or beam drift can occur or the sharpness or the signal to noise ratio (SNR) can be affected. These effects are amplified by charges from previous scans accumulating on the surface of the object.

Negative charge build-up occurs when electrons impinging on the object are absorbed by the material. This can increase the collection of secondary electrons by the detector causing the image to saturate. In addition, geometry distortions can occur. Positive charge build-up occurs when more electrons are emitted from the object than the electron beam provides. The excess positive charges generate a potential barrier for some of the secondary electrons, which prevents them from reaching the detector. Many of the secondary electrons are, thus, attracted back to the surface of the object. Therefore, the image appears darker leading to low contrast and obscured image features.

All of the issues induced by charging are detrimental to measurement data quality. Therefore, several approaches have been proposed to mitigate the charging effect.

One way is to ground the imaged area on the surface of the object by attaching conducting manipulators. However, it is not clear how charges from insulating regions can flow to a manipulator outside the imaged region. In addition, manipulators must be retracted before the object can be moved.

Another way is to charge the area on the surface of the object with a flood gun, either before or after scanning the area on the surface of the object, as, for example, disclosed in EP 1585164 A2. A flood gun is an electromechanical device that provides a steady flow of low-energy electrons to the area on the surface of the object. If the energy of the flood gun's electrons is properly balanced, each impinging flood gun electron knocks out one secondary electron from the target, thereby balancing the charges on the surface of the object. However, flood guns offer limited options for tuning to a specific application. In addition, flood guns are limited to the generation of either positive or negative charges in a given sample. Thus, surface charges of the same sign as the ones generated cannot be balanced.

Another way is to coat the object by depositing thin conducting films on the surface of the object as disclosed, for example, in US 2017/0040228 A1. These coatings allow the charge on the object surface to flow away. However, coating of the object has some disadvantages. The film layer impairs the characteristics of the object surface and influences elemental composition measurements, e.g., by altering the structure contrast. In addition, object coatings are not compatible with tomography applications, where the surface of the object is repeatedly removed by an ion beam.

Another way is to select a first landing energy, which does not cause a charge accumulation on the surface of the object. In this case, the number of emitted electrons balances the number of injected electrons by the first electron beam. However, in most cases such a first landing energy compromises optimal imaging conditions for viewing the structures of interest on the object. The imaging conditions could in most cases be improved by selecting a different first landing energy.

Therefore, it is an aspect of the invention to control the charges on the surface of the object in order to improve the quality of SEM images obtained during electron beam inspection or review. It is another aspect of the invention to improve the speed of obtaining SEM images. It is another aspect of the invention to increase the throughput of metrology, defect inspection and defect review methods and systems. It is another aspect of the invention to reduce the user effort for selecting viewing parameters. It is another aspect of the invention to balance the charges in a simple way without impairing the object or limiting the usability of the method. It is another aspect of the invention to obtain a simple structure of the SEM. It is also an aspect of the invention to control the charges in a way, which mitigates the above-mentioned disadvantages.

The aspects are achieved by the invention specified in the independent claims. Advantageous embodiments and further developments of the invention are specified in the dependent claims.

### SUMMARY

Embodiments of the invention concern methods and systems for balancing positive and negative charges on a surface of an object comprising integrated circuit patterns in a scanning electron microscope.

A first embodiment of the invention involves a method for balancing charges on a surface of an object comprising integrated circuit patterns in a scanning electron microscope, the method comprising: scanning an area on the surface of the object with a first electron beam with a first landing energy one or more times to generate a scanning electron microscopy image of the area from the amount of emitted electrons per dwell point, thereby accumulating charges on the surface of the object; and subsequently scanning the area on the surface of the object with a second electron beam with a second landing energy one or more times such that the charges accumulated on the surface of the object are at least partially balanced. In this way, the parameters of the first electron beam, especially the landing energy, can be adapted to optimize the image quality, since the accumulated charges on the surface of the object are subsequently compensated for by the second electron beam. Therefore, according to an example of the first embodiment of the invention, the first landing energy is selected to optimize the quality of the generated scanning electron microscopy image. In an example, the first landing energy is selected to maximize the electron emission yield of the object. Thus, the quality of the SEM images, e.g., the contrast, the sharpness or the signal to noise ratio, is improved. In an example, the first landing energy has an electron emission yield greater than 1 and the second landing energy has an electron emission yield smaller than 1, or the first landing energy has an electron emission yield smaller than 1 and the second landing energy has an electron emission yield greater than 1. In this way, one electron beam accumulates positive charges and the other electron beam accumulates negative charges. Thus, charges on the surface of the object are compensated for by generating charges of opposite sign and the image quality is improved.

According to an aspect of the example of the first embodiment of the invention, the quality of the generated scanning electron microscopy image is measured by at least one image quality metric from the group comprising contrast, sharpness, distortion, signal to noise ratio, beam drift, magnification variation. These quality metrics can be measured automatically or by a user. In an example, the first landing energy and/or a beam current of the first electron beam and/or a scanning time per area of the first electron beam is selected according to at least one image quality metric. Thus, the first landing energy and/or the beam current and/or the scanning time per area of the first beam column can be adjusted automatically. By optimizing the at least one image quality metric, the image quality can be improved, operating time can be saved and the effort for the user for selecting viewing parameters can be reduced.

According to an example of the first embodiment of the invention, a beam current of the second electron beam and/or a scanning time per area of the second electron beam is selected according to a function of the first landing energy, a beam current of the first electron beam, a scanning time per area of the first electron beam and the second landing energy of the second electron beam. In this way, the electron beam and/or the scanning time per area of the second electron beam can be adjusted to optimize a criterion, e.g., the image quality, an image quality metric, or the scanning time per area, while at the same time the charges on the surface of the object are at least partially balanced.

According to an example of the first embodiment of the invention, the scanning electron microscope comprises a beam column, and the first electron beam and the second electron beam are both generated by said beam column. Thus, a single beam column is used to generate the first electron beam and the second electron beam, e.g., in an alternating way. By using only one beam column a simple structure of the SEM is obtained, since it contains less components. The control unit of the SEM is also less complex, since only one beam column has to be controlled. In addition, less material, space and construction costs are required.

According to an example of the first embodiment of the invention, the area on the surface of the object corresponds to a scan line of the first electron beam. In this way, each scan line is first scanned by the first electron beam and then the accumulated charges are compensated for by the second electron beam. Thus, the accumulated charges are compensated for quickly after their generation. In this way, the image quality is improved.

According to an example of the first embodiment of the invention, the area on the surface of the object is scanned with the second electron beam during the beam fly-back after scanning the area (e.g., a scan line) with the first electron beam. In this way, the additional time required for compensating the accumulated charges can be minimized by using the time required for the beam fly-back. In an example, a scan line is scanned by the first electron beam and the accumulated charges are erased by the second electron beam during the beam fly-back before scanning the next scan line.

According to an example of the first embodiment of the invention, the area on the surface of the object is repeatedly scanned with the first electron beam and subsequently once with the second electron beam, wherein the second electron beam is adjusted to balance the accumulated charges of the repeated scans with the first electron beam, e.g., by adjusting the second landing energy and/or the beam current and/or the scanning time per area of the second electron beam. In this way, for example frame averaging can be carried out, wherein after scanning an area on the surface of the object N times with the first electron beam the accumulated charges are erased by scanning the area once with the second electron beam. The parameters of the second electron beam are adjusted to erase the accumulated charges of the N previous scans of the area.

According to an example of the first embodiment of the invention, the area on the surface of the object is scanned once with the first electron beam and subsequently repeatedly with the second electron beam, wherein the second electron beam is adjusted to balance the accumulated charges of the scan with the first electron beam during the repeated scans with the second electron beam. In this way, for example lower scanning times or beam currents of the second electron beam can be used for compensating for the accumulated charges. This procedure could be advantageous if the beam current and/or the scanning time of the second electron beam cannot be adjusted to compensate for the charges induced by the first electron beam in a single scan.

According to an example of the first embodiment of the invention, the shape, e.g., the diameter, of an electron beam spot generated on the surface of the object by the first electron beam or by the second electron beam is adjusted to or optimized with respect to the first landing energy during scanning of the area on the surface of the object with the first electron beam, and the shape of the electron beam is not adjusted or optimized with respect to the second landing energy during scanning of the area on the surface of the object with the second electron beam. Since the second electron beam is not used for imaging, the shape of the beam spot does not have to be optimized. In this way, fast switching between the first landing energy and the second landing energy is possible without requiring a beam column alignment. Thus, time is saved and the throughput increased. In addition, the method is applicable in cases where a beam column alignment at high frequencies is technically not possible.

According to an example of the first embodiment of the invention, the first electron beam has a diameter smaller than 5 nm, preferably smaller than 4 nm, most preferably smaller than 3 nm. In this way, the resolution of the image is improved and, thus, the image quality.

A scanning electron microscope for examination of an object comprising integrated circuit patterns according to a second embodiment of the invention comprises: a first beam column configured to direct a first electron beam with a first landing energy towards an area on the surface of the object, thereby accumulating charges on the surface of the object; a second beam column configured to direct a second electron beam with a second landing energy towards the area on the surface of the object such that the accumulated charges on the surface of the object are at least partially balanced; and a detector configured to detect emitted electrons from the area on the surface of the object during the scanning of the area with the first electron beam. By using different beam columns for generating the first electron beam and the second electron beam, imaging and erasing can be carried out in a more flexible way, since both beam columns can be controlled independently. In case the second electron beam does not interfere with the imaging process (e.g., if it only generates secondary electrons and imaging is done using back-scattered electrons), imaging and charge erasing can be carried out simultaneously, or the second electron beam can directly follow the scan path of the first electron beam, thereby immediately erasing the charges accumulated by the first electron beam. In this way, the image quality is improved and scanning patterns can be flexibly defined. In addition, time required for imaging and erasing can be saved, thus, increasing the throughput. Furthermore, using separate beam columns for imaging and erasing charges is advantageous, since switching between different landing energies is not required, thus avoiding the risk of a reduced beam spot quality due to a reduced repeatability. Since switching between different landing energies in a single column bears the risk of a reduced beam spot quality (reduced repeatability), a high image quality is ensured in this way. However, using different beam columns for the first electron beam and the second electron beam also requires additional components in the SEM and, thus, more material, space and construction costs.

Therefore, a scanning electron microscope for examination of an object comprising integrated circuit patterns according to the third embodiment of the invention comprises:

a beam column configured to direct a first electron beam with a first landing energy towards an area on the surface of the object, thereby accumulating charges on the surface of the object, and to subsequently direct a second electron beam with a second landing energy towards the area on the surface of the object such that the accumulated charges on the surface of the object are at least partially balanced; and a detector configured to detect emitted electrons from the area on the surface of the object during the scanning of the area with the first electron beam. By using the same beam column for the first electron beam and the second electron beam, the structure of the SEM is simplified, since no additional components are required, thereby saving material, space and construction costs.

According to an example of the third embodiment of the invention, the beam column has a beam booster stage comprising a high voltage source and a combined electrostatic-electromagnetic lens, the high voltage source being configured for accelerating electrons in the first electron beam or in the second electron beam within the beam column, and the electrostatic-electromagnetic lens being configured for decelerating electrons in the first electron beam or in the second electron beam before leaving the beam column, and wherein the beam booster stage of the beam column is configured for controlling the first landing energy of the first electron beam and the second landing energy of the second electron beam. Due to the lower impedance of the beam booster stage compared to the complete high voltage system, switching between different landing energies can be performed quickly. Thus, a fast switching between imaging mode and erasing mode is made possible leading to a higher throughput.

According to an example of the third embodiment of the invention, the beam column includes units providing an electromagnetic field for selectively directing the first electron beam and the second electron beam through different apertures thereby defining the beam current of the first electron beam and the beam current of the second electron beam. Due to the electromagnetic aperture selection, the beam currents of the first electron beam and the second electron beam can be adjusted quickly allowing for a fast switching between imaging mode and erasing mode and, thus, a higher throughput.

According to an example of the second or third embodiment of the invention, the SEM is configured to generate the first electron beam with a diameter smaller than 5 nm, preferably smaller than 4 nm, most preferably smaller than 3 nm. In this way, the resolution of the image is improved and, thus, the image quality.

According to an example of the second or third embodiment of the invention, the SEM comprises a control unit for controlling the first electron beam and the second electron beam according to a method of the first embodiment of the invention described above.

According to an example of the second or third embodiment of the invention, the SEM is configured to measure the quality of the generated scanning electron microscopy image by at least one image quality metric from the group comprising contrast, sharpness, distortion, signal to noise ratio, beam drift, magnification variation. In an example, the SEM is configured to optimize the quality of the generated scanning electron microscopy image by optimizing at least one image quality metric with respect to the first landing energy and/or the beam current and/or the scanning time of the first electron beam. Optimization can, for example, be carried out by a simple grid search over the one or more parameter ranges for the first landing energy and/or the beam current and/or the scanning time of the first electron beam and returning the one or more parameters yielding the best image quality metric value.

According to an example of the second or third embodiment of the invention, the SEM is configured to alternately scan a scan line on the surface of the object with the first electron beam and subsequently erase the accumulated charges by scanning the same scan line with the second electron beam. In an example of the third embodiment of the invention, the SEM is configured to scan the area on the surface of the object, e.g., the scan line, with the second electron beam during the beam fly-back after scanning the area with the first electron beam. In this way, the time for erasing the accumulated charges is minimized, thus increasing the throughput.

According to an example of the second or third embodiment of the invention, the SEM is configured to repeatedly scan the area on the surface of the object with the first electron beam and subsequently once with the second electron beam, wherein the second electron beam is adjusted to balance the accumulated charges of the repeated scans with the first electron beam. In this way, frame averaging for drift compensation can be performed quickly without accumulating charges on the surface of the object, thereby improving the image quality.

According to an example of the second or third embodiment of the invention, the SEM is configured to scan the area on the surface of the object once with the first electron beam and subsequently repeatedly with the second electron beam, wherein the second electron beam is adjusted to balance the accumulated charges of the scan with the first electron beam during the repeated scans with the second electron beam. This procedure could be advantageous if the beam current and/or the scanning time of the second electron beam cannot be adjusted to compensate for the charges induced by the first electron beam in a single scan.

According to an example of the third embodiment of the invention, the SEM is configured to adjust the shape, e.g., the diameter, of an electron beam spot generated on the surface of the object by the first electron beam or by the second electron beam to the first landing energy during scanning of the area on the surface of the object with the first electron beam and to keep the shape of the electron beam spot adjusted to the first landing energy during scanning of the area on the surface of the object with the second electron beam. In this way, fast switching between the first landing energy and the second landing energy is possible since no complete column alignment is required.

The invention described by examples and embodiments is not limited to the embodiments and examples but can be implemented by those skilled in the art by various combinations or modifications thereof.

### BRIEF DESCRIPTION OF DRAWINGS

FIG. 1 shows exemplary SEM images of wafers with reduced image quality due to accumulated charges on the surface of the scanned wafer;

FIG. 2 shows a graph of the total electron emission yield as a function of the landing energy of the electrons of the electron beam;

FIG. 3 shows a flowchart of a method for balancing charges on a surface of an object comprising integrated circuit patterns in a scanning electron microscope;

FIG. 4 illustrates the selection of the first landing energy of the first electron beam and of the second landing energy of the second electron beam;

FIG. 5 shows a scanning electron microscope for examination of an object comprising integrated circuit patterns with a dual beam column setup;

FIG. 6 shows a scanning electron microscope for examination of an object comprising integrated circuit patterns with a single beam column setup;

FIG. 7 illustrates a cross section of a beam column having a beam booster stage; and

FIG. 8 illustrates an electromagnetic aperture changer.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

In a Scanning Electron Microscope (SEM), an electron beam is scanned over the object surface in a raster pattern while a signal from secondary electrons (SE) or back-scattered electrons (BSE) is recorded by specific electron detectors. The electron beam, which typically has an energy ranging from a few hundred eV up to 40 keV, is focused to a spot of about 0.4 nm to less than 5 nm in diameter. Latest generation SEMs can achieve a resolution of 0.4 nm at 30 kV and 0.9 nm at 1 kV. Since the number of emitted electrons in most cases does not balance the number of injected electrons an excess charge remains on the surface of the object. Especially for objects of insulative material, e.g., silicon dioxide, charges build up quickly. The charges affect the image quality causing, e.g., contrast variations, loss of sharpness, distortions, lower signal to noise ratios (SNR), beam drift or magnification variations.

FIG. 1 shows exemplary SEM images 10, 10′ of wafers with reduced image quality due to accumulated charges on the surface of the scanned wafer. On the left-hand side of FIG. 1, the SEM image 10 of a 3D NAND with nominally equal structures exhibits strong contrast variations. On the right-hand side of FIG. 1, the SEM image 10′ of a 3D NAND exhibits strong distortions. To obtain SEM images 10 of high image quality, it is an aspect of the invention to prevent the accumulation of charges on the surface of the scanned object.

One way of preventing the accumulation of surface charges is to select the landing energy of the electrons in the electron beam such that the number of electrons released from the material equals the number of incident electrons. The ratio between the total number of electrons released from a material (independent of their energies) and the number of incident electrons is referred to as the total electron emission yield δ, which is a function of the landing energy Eₚ of the electrons of the electron beam:

$$δ ( {E}_{p} ) = \frac{{I}_{emitted} ( {E}_{p} )}{{I}_{p} ( {E}_{p} )} = \frac{{I}_{B S E} ( {E}_{p} ) + {I}_{S E} ( {E}_{p} )}{{I}_{p} ( {E}_{p} )} ,$$

where I_{emitted} denotes the emitted current, I_{BSE} the current of the back-scattered electrons, ISE the current of the secondary electrons and Iₚ the beam current of the electron beam.

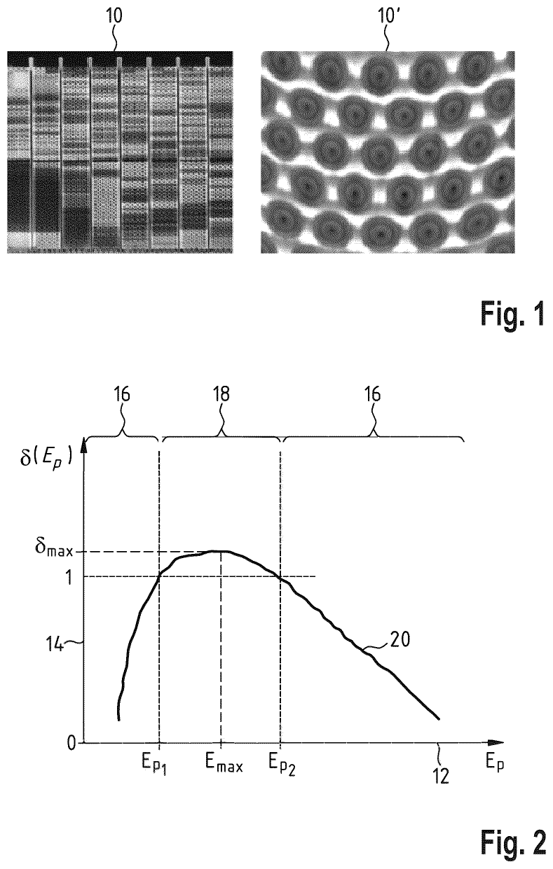

FIG. 2 shows an example of a graph 20 of the total electron emission yield δ as a function of the landing energy Eₚ of the electrons of the electron beam. The horizontal axis 12 indicates the landing energy Eₚ and the vertical axis 14 the total electron emission yield δ(Eₚ). The landing energies Eₚ₁, and Eₚ₂, correspond to a total electron emission yield of 1. Thus, these are the only landing energies which prevent charge built-up on the surface of the object, since the number of incident electrons in the electron beam equals the number of emitted electrons from the surface of the object. For landing energies below Eₚ₁ or above Eₚ₂ negative charge built-up 16 occurs on the surface of the object, whereas for landing energies between Eₚ₁ and Eₚ₂ positive charge built-up 18 occurs on the surface of the object. However, the landing energies Eₚ₁ and Eₚ₂ usually are not optimized for image quality. For example, an improved contrast or SNR can be obtained by maximizing the total electron emission yield to δₘₐₓ by using a landing energy Eₘₐₓ, which, however, leads to a strong positive charge-up 18 of the surface of the object. Therefore, compromises between the charging on the surface of the object and the image quality usually have to be made. It is, therefore, an aspect of the invention to balance charges on the surface of the object without compromising the image quality.

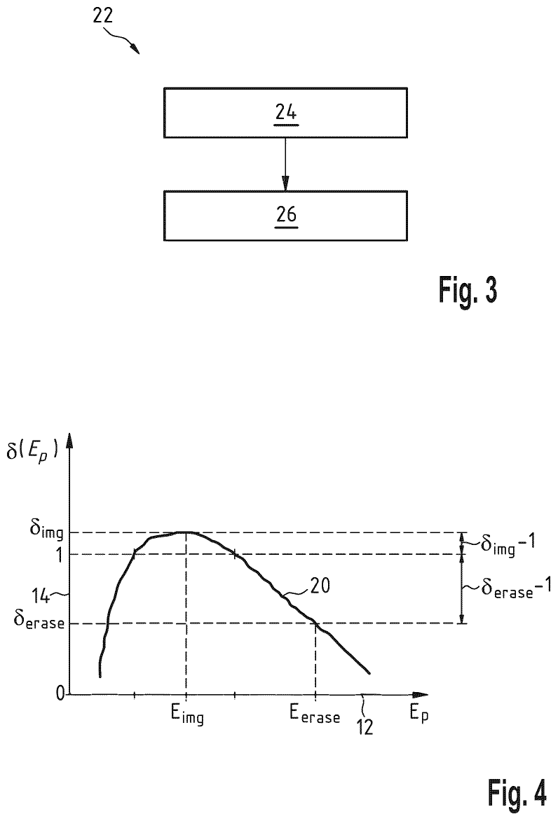

A flowchart of a method 22 for balancing charges on a surface of an object comprising integrated circuit patterns in a scanning electron microscope according to a first embodiment of the invention is shown in FIG. 3. The method 22 comprises scanning an area on the surface of the object with a first electron beam with a first landing energy one or more times to generate a scanning electron microscopy image of the area from the amount of emitted electrons per dwell point, thereby accumulating charges on the surface of the object, in an imaging step 24; and subsequently scanning the area on the surface of the object with a second electron beam with a second landing energy one or more times such that the charges accumulated on the surface of the object are at least partially balanced, in an erasing step 26.

Since the accumulated charges on the surface of the object are erased in the erasing step 26, the parameters of the first electron beam (the first landing energy, the beam current and the scanning time, etc.) can be selected to optimize the image quality without making compromises. For example, the first landing energy can be selected to maximize the total electron emission yield of the object. In this way, the contrast and the sharpness can be maximized. In another example, the object contains two or more materials, and the first landing energy can be selected to optimize the contrast between the materials to best visualize the transition.

However, the total electron emission yield depends on the material and the geometry of the surface of the object. For example, 3D memory structures often contain deep holes wherein the electrons can get stuck, thus reducing the number of SE and BSE. The following table shows the maximum total electron emission yield δₘₐₓ, the corresponding landing energy Eₘₐₓ, and the landing energies E₁ and E₂ for obtaining a total electron emission yield δ=1.

| Material | δₘₐₓ | Eₘₐₓ[eV] | E₁[eV] | E₂[eV] |
|---|---|---|---|---|
| Cu | 1.3-1.4 | 600-700 | 200-220 | 1500-2700 |
| W | 1.35-1.4 | 600-700 | 220-250 | 2900 |
| Si | 1.0-1.1 | 250-300 | 90-200 | 400-500 |
| SiO₂ | 2.1-2.9 | 400 | — | 1150 |
| Al | 0.85-0.95 | 300-400 | — | — |

Since the geometry of the surface of the object is usually unknown, the total electron emission yield of a given object can often only be estimated. The graph 20 can, for example, be simulated for a specific material and a planar surface, which can then serve as a starting point for finding a first landing energy optimizing the image quality. If the object contains two or more materials the graphs 20 for the different materials can be compared and an average value for a first landing energy can be determined from the graphs 20 as a starting point for selecting the first landing energy.

According to an example of the first embodiment of the invention, the quality of the generated scanning electron microscopy image is measured by at least one image quality metric from the group comprising contrast, sharpness, distortion, signal to noise ratio, beam drift, magnification variation. These image quality metrics can be measured automatically or by a user by use of experiments.

The contrast can, for example, be measured as the difference or the ratio of the brightest intensity and the darkest intensity in the image. The sharpness can, for example, be measured by the so-called rise-distance of an edge in the image, that is the distance between a pixel with around 10% of the edge intensity and a pixel with around 90% of the edge intensity. The lower the rise-distance the sharper is the image. Alternatively, the contrast can be measured relative to different frequencies in the image resulting in a modulation transfer function (MTF). Distortion can, for example, be measured by computing the mean squared error of an original image and an acquired image. Radial distortion can, for example, be measured by detecting at least three circular line segments in the image and optimizing a quadratic polynomial comprising the distortion coefficients. Alternatively, the distortion of an image can be measured by finding circles in the image and comparing the average length of diameters of the distorted circle to the maximum diameter. The SNR can, for example, be defined as the ratio of the mean value of the signal and the standard deviation of the noise. Both values can, for example, be estimated from an image region of homogeneous intensity, e.g., by computing the mean intensity and the standard deviation of the intensity. Beam drift can, for example, be measured by estimating the movement of the scanned object in consecutive images, e.g., by use of image registration methods. Magnification variations can be detected, for example, by comparing the size of identical structures in the image, or by measuring a feature of known size in the image and comparing the measured feature size to the known feature size, or by measuring pitches in regular patterns in the image and comparing the measured pitches to known pitches.

Instead of measuring the image quality, the remaining charges on the surface of the object could also be estimated by measuring a discharge current from the surface of the object to the ground.

According to an example of the first embodiment of the invention, the first landing energy and/or a beam current of the first electron beam and/or a scanning time per area of the first electron beam are selected to optimize at least one image quality metric.

FIG. 4 illustrates a method for the selection of the first landing energy of the first electron beam and of the second landing energy of the second electron beam. The first landing energy E_{img} of the first electron beam is selected such that the quality of the generated SEM image 10 is optimized. For example, the first landing energy E_{img} can be selected to maximize the total electron emission yield of the object yielding δ_{img}=δₘₐₓ as shown in FIG. 3. Then the beam current and the scanning time per area of the first electron beam are adjusted to optimize the image. For example, if the beam current is increased to reduce the scanning time per area in order to increase the throughput, the image quality, e.g., the sharpness, can deteriorate. Thus, the beam current can be selected to optimize the image quality, and the scanning time per area can be reduced as much as possible without affecting the image quality. In another example, in case of moving objects a short scanning time per area is required, which can be selected in combination with a high beam current to optimize the image quality.

The second electron beam can then be adapted to at least partially erase the charges on the surface of the object by selecting a second landing energy Eₑᵣₐₛₑ corresponding to a total electron emission yield δₑᵣₐₛₑ. If the first landing energy E_{img} corresponds to a total electron emission yield δ_{img}>1 then the second landing energy Eₑᵣₐₛₑ is selected such that the corresponding total electron emission yield δₑᵣₐₛₑ<1 or vice versa. In this way, the first electron beam generates a positive charge-up, which is balanced by the second electron beam, which generates a negative charge-up or vice versa.

If the material and/or the geometry of the surface of the object and, thus, the total electron emission yield is unknown, approximate graphs 20 or tables can be used. If the material is known but not the geometry of the surface of the object, the total emitted electron yield can be obtained by simulations. Alternatively, positive and negative charging can be diagnosed from the acquired SEM images experimentally as follows: first, an area on the surface of the object is irradiated for a few seconds using a selected first landing energy. Then the area is viewed at a reduced magnification, e.g., by a factor of five. If a bright raster pattern appears, which may slowly disappear upon going to the lower magnification, negative charging is likely. If, on the contrary, a dark raster pattern appears, which possibly quickly disappears, positive charging is likely.

After selecting the first landing energy, the beam current and the scanning time per area of the first electron beam and the second landing energy of the second electron beam, the beam current and/or the scanning time per area of the second electron beam can be adapted.

According to an example of the first embodiment of the invention, the beam current and/or the scanning time per area of the second electron beam are adapted according to a function of the first landing energy, a beam current of the first electron beam, a scanning time per area of the first electron beam and the second landing energy of the second electron beam.

Let E_{img} indicate the first landing energy, I_{img} the beam current and T_{img} the scan time per area of the first electron beam, and let Eₑᵣₐₛₑ indicate the second landing energy, Iₑᵣₐₛₑ the beam current and Tₑᵣₐₛₑ the scan time per area of the second electron beam. Then the charges Q accumulated on the surface of the object can be measured by

$$Q = ( {I}_{emitted} - {I}_{i m g} ) {T}_{i m g} = ( δ ( {E}_{i m g} ) {I}_{i m g} - {I}_{i m g} ) {T}_{i m g} = ( δ ( {E}_{i m g} ) - 1 ) {I}_{i m g} {T}_{img} ,$$

where I_{emitted} is the beam current emitted from the surface of the object.

In order to balance the accumulated charges on the surface of the object, the following balancing condition must be fulfilled

$$( δ ( {E}_{i m g} ) - 1 ) {I}_{img} {T}_{i m g} = - ( δ ( {E}_{e r a s e} ) - 1 ) {I}_{e r a s e} {T}_{e r a s e} \qquad ( 1 )$$

as shown in FIG. 4. Thus, the following function can be used to select the beam current and the scanning time per area of the second electron beam, wherein the function maps to the product of the beam current and the scanning time per area:

$$f ( {E}_{img} , {I}_{img} , {T}_{img} , {E}_{e r a s e} ) := \frac{( δ ( {E}_{i m g} ) - 1 ) {I}_{i m g} {T}_{i m g}}{- ( δ ( {E}_{e r a s e} ) - 1 )} = {I}_{e r a s e} {T}_{e r a s e} .$$

Any combination of a beam current and scanning time per area of the second electron beam fulfilling this function can be used to approximately balance the accumulated charges on the surface of the object-provided that the scanned area of the first electron beam and the scanned area of the second electron beam overlap to a large extent. If the material and, thus, the total electron emission yield of the object, is known and the surface of the object corresponds to a plane this equation exactly balances the accumulated charges.

In order to partially balance the accumulated charges, it is sufficient if δ(E_{img})−1 and δ(Eₑᵣₐₛₑ)−1 have opposite signs, i.e.,

$$( δ ( {E}_{i m g} ) - 1 ) ( δ ( {E}_{e r a s e} ) - 1 ) < 0 .$$

As long as the beam spot size is larger than the pixel size the above condition (1) can also be formulated in terms of pixels sizes Aₚₓ and dwell times τ per pixel, where A_{scan} is the scanned area, by replacing

$${T}_{i m g} = {τ}_{img} \frac{{A}_{s c a n}}{{A}_{px , img}} and {T}_{e r a s e} = {τ}_{e r a s e} \frac{{A}_{s c a n}}{{A}_{px , erase}}$$

yielding

$$( δ ( {E}_{i m g} ) - 1 ) {I}_{i m g} \frac{{τ}_{i m g}}{{A}_{px , img}} = - ( δ ( {E}_{e r a s e} ) - 1 ) {I}_{e r a s e} \frac{{τ}_{e r a s e}}{{A}_{px , erase}} .$$

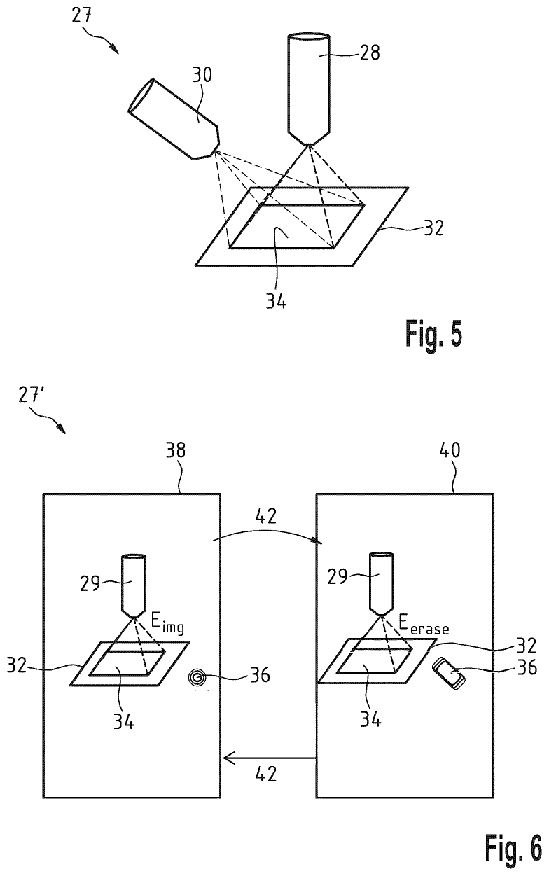

The first electron beam and the second electron beam can be generated by the same beam column as shown in FIG. 6 or by different beam columns as shown in FIG. 5. According to an example of the first embodiment of the invention, the scanning electron microscope comprises a beam column, and the first electron beam and the second electron beam are both generated by said beam column.

The scanning and erasing process can be carried out in different ways. In an example, the area 34 on the surface 32 of the object corresponds to a scan line of the first electron beam. Thus, the area 34 on the surface 32 of the object is divided into scan lines. After scanning a scan line with the first electron beam, the same scan line is scanned with the second electron beam for erasing the accumulated charges. Thus, imaging and erasing is carried out alternately. Alternatively, a number of scan lines, e.g., a full image, is scanned by the first electron beam, and then the same area is subsequently scanned by the second electron beam to erase the accumulated charges. Especially if high frequency switching between imaging and erasing is not possible, e.g., for technical reasons, erasing the accumulated charges after scanning multiple scan lines or larger areas on the surface of the object can be advantageous.

According to an example of the first embodiment of the invention, the area 34 on the surface 32 of the object is scanned with the second electron beam during the beam fly-back after scanning the area 34 with the first electron beam. Since erasing charges by scanning the area on the surface of the object with a second electron beam takes time, which might result in a lowered throughput, this option can be used to limit the additional time for erasing charges to a minimum. Imaging is then done during the beam forward propagation, while the beam fly-back to the start of the next scan line is used for balancing the accumulated charges. In this way, the speed of obtaining the SEM images as well as the throughput is increased.

According to an example of the first embodiment of the invention, the area on the surface of the object is repeatedly scanned with the first electron beam and subsequently once with the second electron beam, wherein the second electron beam is adjusted to balance the accumulated charges of the repeated scans with the first electron beam. This scanning and erasing process is especially interesting for drift compensation frame averaging and for tomography applications.

Drift compensation frame averaging is carried out to improve the image quality in case of a moving object. To minimize the impact of the movement, short scanning times per area of the first electron beam are selected, which can be compensated for by high beam currents. The movement of the object can be compensated for by using registration techniques from image processing. However, the short scanning times per area lead to low SNRs. To obtain an image with an improved SNR the registered images are averaged.

In tomography applications slices of the object are imaged by alternatingly imaging the surface 32 of the object several times and then removing the upper slice by use of an ion beam. This process is called milling. During this process, multiple images are acquired of the same area with short scanning times per area. The multiple images can be averaged to obtain a high SNR. In addition, the ion beam induces additional charges on the surface 32 of the object, which should be balanced to maintain a high image quality. Frame averaging for SNR improvement is for example, disclosed in US provisional application 63/328418 filed on Apr. 7, 2022, which is hereby incorporated by reference into this disclosure.

For drift compensation and tomography applications, the same area 34 or, respectively, adjacent areas in milling direction on the surface 32 of the object are scanned multiple times. Afterwards the charges accumulated during the multiple scans are balanced. Therefore, the second landing energy, the beam current and the scanning time of the second electron beam must be adapted to erase all accumulated charges in a single scan by the first electron beam and, in case of tomography applications, of the focused ion beam as well. In this case the above condition (1) must be modified that the erase charge on the right-hand side matches the charge deposit by the multiple scans with the first electron beam and, in case of tomography applications, of the focused ion beam as well. For example, if the area 34 on the surface 32 of the object is scanned N times, the left-hand side of the equation (1) is multiplied by N.

According to an example of the first embodiment of the invention, the area 34 on the surface 32 of the object is scanned once with the first electron beam and subsequently repeatedly with the second electron beam, wherein the second electron beam is adjusted to balance the accumulated charges of the scan with the first electron beam during the repeated scans with the second electron beam. In this case the above condition (1) must be modified such that the multiple erase charges on the right-hand side match the charge deposited by the first electron beam. For example, if the charges on the surface 32 of the object are erased N times, the right-hand side of the equation (1) is multiplied by N.

For any of the above-described options, it must be ensured that during scanning the area 34 on the surface 32 of the object with the second electron beam the collection of the emitted electrons in the SEM is suspended.

Switching between the first landing energy and the second landing energy in one beam column is usually not desirable with a high frequency, since switching the landing energy requires a new column alignment (including focus wobbling, etc.) to ensure optimal image quality. However, provided that switching between landing energies without any further beam column adjustments leads to repeatable electron beam spot shapes, it is possible to optimize the electron beam spot only for the first landing energy and accept the lower electron beam spot quality during erasing with the second landing energy as shown in FIG. 6, since the electron beam spot 36 is not used for imaging but only for erasing.

Therefore, according to an example of the first embodiment of the invention, the shape, e.g., the diameter, of an electron beam spot 36 generated on the surface 32 of the object by the first electron beam or by the second electron beam is adjusted to the first landing energy during scanning of the area 34 on the surface 32 of the object with the first electron beam, and the shape is not adjusted to the second landing energy during scanning of the area 34 on the surface 32 of the object with the second electron beam as illustrated in FIG. 6. The first electron beam and the second electron beam are generated by a beam column which is controlled by beam column parameters, wherein the beam column parameters comprise the landing energy, the beam current, the scanning time of the electron beam, lens currents, deflection voltages, extraction voltages, grid voltages, etc., and the beam column parameters are adjusted to optimize the shape of an electron beam spot 36 generated on the surface 32 of the object 64 by the first electron beam during scanning of the area 34 on the surface 32 of the object 64 with the first electron beam, and the beam column parameters are retained except for the landing energy and, possibly, the beam current and/or the scanning time during scanning of the area 34 on the surface 32 of the object 64 with the second electron beam. Thus, during the imaging step 24 the diameter of the electron beam spot 36 is small in order to optimize the imaging quality. Provided that switching back from the second landing energy to the first landing energy restores the electron beam spot 36 without the need for spot optimization the electron beam spot 36 can remain adjusted to the first landing energy also during charge erasing. Therefore, during the erasing step 26 the diameter of the electron beam spot 36 is not modified, since it does not influence the imaging quality but is only used for erasing charges. Thus, the electron beam spot is not optimized with respect to the second landing energy but remains adjusted to the first landing energy instead. In this way, time for the usually required adjustment of the beam column is saved, thus increasing the throughput of defect review or defect analysis methods and systems.

According to an example of the first embodiment of the invention, the first electron beam has a diameter smaller than 5 nm, preferably smaller than 4 nm, most preferably smaller than 3 nm.

FIG. 5 shows a scanning electron microscope 27 for examination of an object comprising integrated circuit patterns with a dual beam column setup according to the second embodiment of the invention. The scanning electron microscope 27 comprises: a first beam column 28 configured to direct a first charged particle electron beam with a first landing energy towards an area 34 on the surface 32 of the object, thereby accumulating charges on the surface 32 of the object; a second beam column 30 configured to direct a second charged particle electron beam with a second landing energy towards the area 34 on the surface 32 of the object such that the accumulated charges on the surface 32 of the object are at least partially balanced; and a detector configured to detect emitted electrons from the area on the surface 32 of the object during the scanning of the area with the first electron beam. The detector can be arranged inside the first beam column 28 or outside the first beam column 28.

The first beam column 28 is used for imaging the area 34 on the surface 32 of the object, whereas the second beam column 30 is used to erase the charges in the scanned area 34 on the surface 32 of the object. While the first beam column 28 must fulfill high quality standards, e.g., with respect to beam spot size and scan linearity, this is not required for the second beam column 30 since it is not used for imaging. By using two beam columns 28, 30 the imaging step 24 and the erasing step 26 can be coordinated in a flexible way, since the scanning path of the second column 28 can be controlled independently from the scanning path of the first column 30. For example, the second beam column 28 can erase the accumulated charges immediately after scanning by following the scanning path on the surface 32 of the object of the first beam column 28. In another example, the second beam column 28 can erase the charges accumulated in the area 34 by using a different scanning path than the first column 28. By using two beam columns 28, 30 the imaging step 24 and the erasing step 26 can be carried out simultaneously, for example if a SEM is used as a first beam column for imaging and a FIB-SEM is used as a second beam column for erasing the accumulated charges. Since the SEM generates back-scattered electrons (BSE) and secondary electrons (SE), while the FIB-SEM only generates secondary electrons (SE), the second charged particle beam can be used simultaneously without interfering with the imaging process if only the BSEs are used for imaging. In this way, the time required for imaging and erasing can be reduced and the throughput of defect review or defect analysis methods and systems can be improved.

FIG. 6 shows a scanning electron microscope 27′ for examination of an object comprising integrated circuit patterns with a single beam column setup according to a third embodiment of the invention. The scanning electron microscope 27′ comprises: a beam column 29 configured to direct a first electron beam with a first landing energy towards an area 34 on the surface 32 of the object, thereby accumulating charges on the surface 32 of the object, and to subsequently direct a second electron beam with a second landing energy towards the area 34 on the surface 32 of the object such that the accumulated charges on the surface 32 of the object are at least partially balanced; and a detector configured to detect emitted electrons from the area 34 on the surface 32 of the object during the scanning of the area 34 with the first electron beam. In the single beam column setup only a single beam column 29 is used for imaging and charge erasing. In an imaging configuration 38 the beam column 29 is configured for scanning the area 34 on the surface 32 of the object to generate a SEM image of high quality. The first landing energy of the first electron beam can, for example, be selected to optimize the imaging quality as described above. In an erasing configuration 40 the beam column 29 is configured for erasing the accumulated charges in the scanned area 34 on the surface 32 of the object. The second landing energy of the second electron beam can, for example, be selected with respect to the total electron emission yield δ of the first landing energy of the first electron beam as described above. The configuration of the beam column 29 alternates between the imaging configuration 38 and the erasing configuration 40 as shown by the arrows 42. By using only a single beam column 29 the structure of the SEM 27′ is simplified, thus requiring less material, space and construction costs. The detector can be arranged within the beam column 29 or outside the beam column 29.

The beam column 29 can be configured such that the shape, e.g., the diameter, of an electron beam spot 36 generated on the surface 32 of the object by the first electron beam or by the second electron beam is adjusted to the first landing energy during scanning of the area 34 on the surface 32 of the object with the first electron beam, and the shape of the electron beam is not adjusted to the second landing energy during scanning of the area 34 on the surface 32 of the object with the second electron beam, as described above. FIG. 6 shows the shape of the beam spot 36 in the imaging configuration 38, where the beam spot is circular and of small diameter and, thus, optimized to obtain a high image quality. In the erasing configuration 40 the shape of the beam spot 36 is not adjusted to the second landing energy, thus, yielding an aberrated beam spot, e.g., a beam spot 36 which is non-circular or of a larger diameter, which is not optimized for image quality.

One problem arising for the SEM with single beam column setup is the high impedance of the SEM for switching between the first landing energy of the first electron beam and the second landing energy of the second electron beam. Due to this high impedance, switching between the first landing energy and the second landing energy is slow.

In addition, the beam current of the first electron beam and the second electron beam has to be adjusted at the same speed as the landing energy. However, a mechanical aperture control is slow and requires a beam-alignment to center the electron beam within the aperture in order to prevent asymmetric electron beams. Therefore, a mechanical aperture control is not suitable for a fast switching between beam currents.

In an example, the SEM comprises at least two components for controlling the first landing energy and the second landing energy, wherein the two components have a different response time. In this case, the component with the faster response time is selected for controlling the first landing energy and the second landing energy.

In order to allow for a fast switching between the imaging configuration 38 and the erasing configuration 40 in a SEM with single beam column setup as shown in FIG. 6, special design features of a SEM, which were actually designed for a different purpose, can be used. These design features are described in the following.

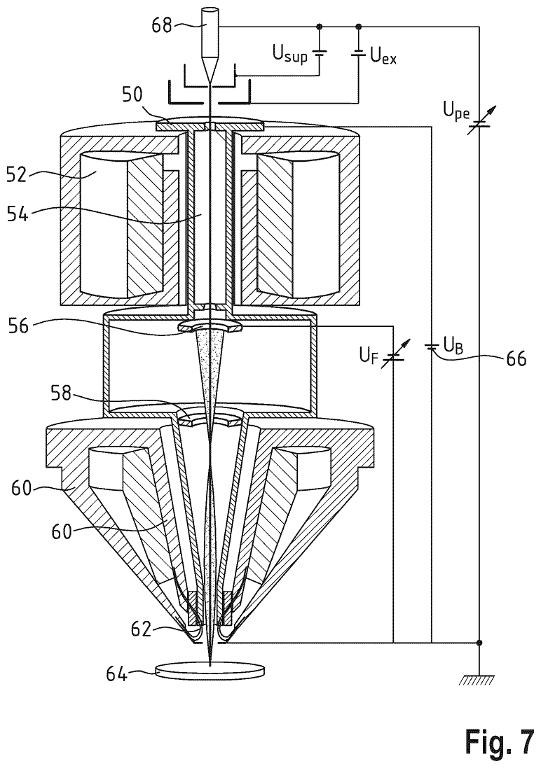

FIG. 7 illustrates a cross section of a beam column 29 having a beam booster stage 50. The scanning electron microscope 27′ with a single beam column setup can include a beam column 29 comprising a beam booster stage 50. The beam booster stage 50 comprises a high voltage source 66 and an electrostatic-electromagnetic lens comprising a combination of an electrostatic lens 62 and an electromagnetic lens 60, the high voltage source 66 being configured for accelerating electrons in the first electron beam or in the second electron beam within the beam column 29, and the electrostatic-electromagnetic lens being configured for decelerating electrons in the first electron beam or in the second electron beam before leaving the beam column 29, and wherein the beam booster stage 50 of the beam column 29 is configured for controlling the first landing energy of the first electron beam and the second landing energy of the second electron beam. The SEM comprises a gun 68 for emitting electrons. A Schottky field emitter can, for example, serve as a gun 68. The SEM also comprises a field lens 52, which can include one or more condensers. An electromagnetic aperture changer 54 can be used to control the aperture as described below. An annular BSE detector 56 is arranged in the SEM for detecting back-scattered electrons, and an annular SE detector 58 is arranged in the SEM for detecting secondary electrons. In this way, both BSE and SE can be collected separately. The BSE detector 56 usually generates images with lower SNR, since fewer electrons are generated, but the BSE can penetrate deeper into the object than the SE due to their higher energy. The SE detector 58 usually generates images of higher SNR, but the SE only stem from the surface of the object due to their lower energy. Therefore, the SEM can be configured to allow the user to select between images generated by the annular BSE detector 56 and images generated by the annular SE detector 58. In this way, the imaging modality with the best imaging quality can be selected.

The SEs and BSEs generated at the impact point of the electron beam are intercepted by the low electrical field of the column at the sample surface. They are accelerated by the field of the electrostatic lens 62. Due to the excitation of the electromagnetic lens 60 the low energy SEs are projected onto the annular SE detector 58. The high angle BSEs originated close to the impact point of the electron beam, are focused into a beam-waist at the hole of the annular SE detector 58 and detected by the integrated energy and angle selective annular BSE detector 56 with the filtering grid voltage U_{F}. A small amount of SEs pass through the hole of the annular SE detector 58 and would be observed by the annular BSE detector 56. To prevent detection of these SEs a filtering grid is installed in front of the annular BSE detector 56. By simply switching the filtering grid the SEs will be rejected and only the BSEs will be detected. The unique combination of the annular SE detector 58 and the annular BSE detector 56 enables simultaneous imaging and mixing of clear high contrast topography (SE) and pure compositional contrast (BSE). Below a landing energy of 1.5 kV the filtering grid has the additional function of selecting the desired energy of the BSEs. The operator can select the threshold energy of inelastic scattered BSEs to enhance contrast and resolution. For example, with a landing energy of 1.5 KV and the filtering grid on 1.4 kV, the SE will be suppressed and the BSE landing energy on the annular BSE detector 56 will be in the range of 1.4-1.5 kV.

Electrons are emitted from the heated filament of the gun 68 while an electrical field is excited by applying the extractor voltage (Uₑₓ). To suppress unwanted thermionic emission from the shank of the gun, e.g., the Schottky field emitter, a suppressor voltage (Uₛᵤₚ) can be applied as well. The emitted electrons are accelerated by the acceleration voltage (Uₚₑ). The beam booster stage 50 with booster voltage (U_{b}) is integrated directly after the anode. This guarantees that the energy of the electrons in the entire beam path is always much higher than the acceleration voltage (Uₚₑ) selected by the user. This considerably reduces the sensitivity of the first electron beam and the second electron beam to magnetic stray fields, minimizes the beam broadening and reduces beam aberrations, thus improving the imaging quality.

Apart from improving the image quality, the beam booster stage 50 has been identified by the inventors as a means for fast switching between the first landing energy of the first electron beam and the second landing energy of the second electron beam due its lower impedance than e.g., Uex. The low impedance leads to a low response time of the beam column 29 during changing of the landing energy. Thus, by using the beam booster stage 50 of the SEM for controlling the first landing energy and the second landing energy, a fast switching between landing energies is possible.

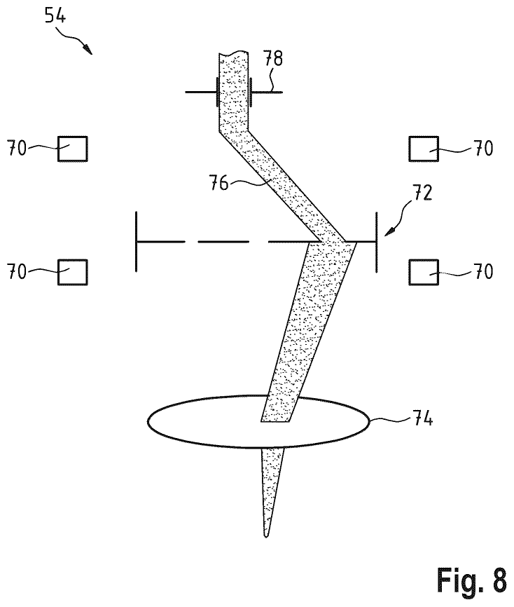

FIG. 8 illustrates an electromagnetic aperture changer 54, which can be included in the beam column 29, for example in the beam booster stage 50 in FIG. 7. The electromagnetic aperture changer 54 includes units 70 providing an electromagnetic field for selectively directing the electron beam 76 through different apertures 72 thereby defining the beam current of the electron beam 76. By use of the electromagnetic aperture changer 54 the beam current of the first electron beam and the beam current of the second electron beam can be controlled. The electron beam 76 enters through an opening 78. The electromagnetic field is controlled such that the electron beam 76 is directed towards one of the apertures 72 selected by a user before traversing the lens 74. Instead of mechanically selecting an aperture 72, which is slow and requires beam-alignment for centering the electron beam with respect to the aperture 72, the electron beam is directed electromagnetically, which is fast and does not require beam-alignment. Thus, by using the aperture changer 54 for controlling the beam current of the first electron beam and the beam current of the second electron beam, a fast switching between beam currents is possible.

According to an example of the second or third embodiment of the invention, the scanning electron microscope 27, 27′ is configured to generate the first electron beam with a diameter smaller than 5 nm, preferably smaller than 4 nm, most preferably smaller than 3 nm.

According to an example of the second or third embodiment of the invention, the scanning electron microscope 27, 27′ further comprises a control unit for controlling the first electron beam and the second electron beam according to a method for balancing charges according to the first embodiment of the invention described above.

The methods disclosed herein can, for example, be used during research and development of objects comprising integrated circuit patterns or during high volume manufacturing of objects comprising integrated circuit patterns, and for defect review and analysis.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

The following clauses contain preferred embodiments of the invention:

1. A method 22 for balancing charges on a surface 32 of an object 64 comprising integrated circuit patterns in a scanning electron microscope 27, 27′, the method 22 comprising:
Scanning an area 34 on the surface 32 of the object 64 with a first electron beam with a first landing energy one or more times to generate a scanning electron microscopy image of the area 34 from the amount of emitted electrons per dwell point, thereby accumulating charges on the surface 32 of the object 64; and
Subsequently scanning the area 34 on the surface 32 of the object 64 with a second electron beam with a second landing energy one or more times such that the charges accumulated on the surface 32 of the object 34 are at least partially balanced.

2. The method of clause 1, wherein the first landing energy is selected to optimize the quality of the generated scanning electron microscopy image.

3. The method of clause 2, wherein the quality of the generated scanning electron microscopy image is measured by at least one image quality metric from the group comprising contrast, sharpness, distortion, signal to noise ratio, beam drift, magnification variation.

4. The method of clause 2 or 3, wherein the first landing energy and/or a beam current of the first electron beam and/or a scanning time per area of the first electron beam are selected according to at least one image quality metric.

5. The method of clause 4, wherein the at least one image quality metric is optimized.

6. The method of any one of clauses 1 to 5, wherein the first landing energy is selected to maximize the electron emission yield of the object 64.

7. The method of any one of the preceding clauses, wherein the first landing energy has an electron emission yield greater than 1 and the second landing energy has an electron emission yield smaller than 1, or wherein the first landing energy has an electron emission yield smaller than 1 and the second landing energy has an electron emission yield greater than 1.

8. The method of any one of the preceding clauses, wherein a beam current of the second electron beam and/or a scanning time per area of the second electron beam is selected according to a function of the first landing energy, a beam current of the first electron beam, a scanning time per area of the first electron beam and the second landing energy of the second electron beam.

9. The method of any one of the preceding clauses, wherein the scanning electron microscope 27′ comprises a beam column 29, and wherein the first electron beam and the second electron beam are both generated by said beam column 29.

10. The method of any one of the preceding clauses, wherein the area 34 on the surface 32 of the object 64 corresponds to a scan line of the first electron beam.

11. The method of any one of the preceding clauses, wherein the area 34 on the surface 32 of the object 64 is scanned with the second electron beam during the beam fly-back after scanning the area 34 with the first electron beam.

12. The method of any one of the preceding clauses, wherein the area 34 on the surface 32 of the object 64 is repeatedly scanned with the first electron beam and subsequently once with the second electron beam, wherein the second electron beam is adjusted to balance the accumulated charges of the repeated scans with the first electron beam.

13. The method of any one of the preceding clauses, wherein the area 34 on the surface 32 of the object 64 is scanned once with the first electron beam and subsequently repeatedly with the second electron beam, wherein the second electron beam is adjusted to balance the accumulated charges of the scan with the first electron beam during the repeated scans with the second electron beam.

14. The method of any one of the preceding clauses, wherein the shape of an electron beam spot 36 generated on the surface 32 of the object 64 by the first electron beam or by the second electron beam is adjusted to the first landing energy during scanning of the area 34 on the surface 32 of the object 64 with the first electron beam, and the shape of the electron beam spot is not adjusted to the second landing energy during scanning of the area 34 on the surface 32 of the object 64 with the second electron beam.

15. A scanning electron microscope 27 for examination of an object 64 comprising integrated circuit patterns, the scanning electron microscope 27 comprising:
a first beam column 28 configured to direct a first electron beam with a first landing energy towards an area 34 on the surface 32 of the object 64, thereby accumulating charges on the surface 32 of the object 64;
a second beam column 30 configured to direct a second electron beam with a second landing energy towards the area 34 on the surface 32 of the object 64 such that the accumulated charges on the surface 32 of the object 64 are at least partially balanced; and
a detector configured to detect emitted electrons from the area 34 on the surface 32 of the object 64 during the scanning of the area 34 with the first electron beam.

16. A scanning electron microscope 27′ for examination of an object 64 comprising integrated circuit patterns, the scanning electron microscope 27′ comprising:
a beam column 29 configured to direct a first electron beam with a first landing energy towards an area 34 on the surface 32 of the object 64, thereby accumulating charges on the surface 32 of the object 64, and to subsequently direct a second electron beam with a second landing energy towards the area 34 on the surface 32 of the object 64 such that the accumulated charges on the surface 32 of the object 64 are at least partially balanced; and
a detector configured to detect emitted electrons from the area 34 on the surface 32 of the object 64 during the scanning of the area 34 with the first electron beam.

17. The scanning electron microscope 27′ of clause 16, wherein the beam column 29 has a beam booster stage 50 comprising a high voltage source 66 and a combined electrostatic-electromagnetic lens, the high voltage source 66 being configured for accelerating electrons in the first electron beam or in the second electron beam within the beam column 29, and the electrostatic-electromagnetic lens being configured for decelerating electrons in the first electron beam or in the second electron beam before leaving the beam column 29, and wherein the beam booster stage 50 of the beam column 29 is configured for controlling the first landing energy of the first electron beam and the second landing energy of the second electron beam.

18. The scanning electron microscope 27′ of clause 16 or 17, wherein the beam column 29 includes units 70 providing an electromagnetic field for selectively directing the first electron beam and the second electron beam through different apertures 72 thereby defining the beam current of the first electron beam and the beam current of the second electron beam.

19. The scanning electron microscope 27, 27′ of any one of clauses 15 to 18 configured to generate the first electron beam with a diameter smaller than 5 nm, preferably smaller than 4 nm, most preferably smaller than 3 nm.

20. The scanning electron microscope 27, 27′ of any one of clauses 15 to 19, further comprising a control unit for controlling the first electron beam and the second electron beam according to a method for balancing charges of any one of clauses 1 to 14.

In a general aspect, the invention relates to a method 22 for balancing charges on a surface 32 of an object 64 comprising integrated circuit patterns in a scanning electron microscope 27, 27′, the method 22 comprising: scanning an area 34 on the surface 32 of the object 64 with a first electron beam with a first landing energy one or more times to generate a scanning electron microscopy image of the area 34 and subsequently scanning the area 34 on the surface 32 of the object 64 with a second electron beam with a second landing energy one or more times such that the charges accumulated on the surface 32 of the object 34 are at least partially balanced. The invention also relates to scanning electron microscopes 27, 27′ with a single or dual beam column setup for imaging and erasing the accumulated charges.

Reference number list

| | |
|---|---|
| 10, 10′ | SEM image |
| 12 | Horizontal axis |
| 14 | Vertical axis |
| 16 | Negative charge built-up |
| 18 | Positive charge build-up |
| 20 | Graph |
| 22 | Method |
| 24 | Imaging step |
| 26 | Erasing step |
| 27, 27′ | Scanning electron microscope |
| 28 | First beam column |
| 29 | Beam column |
| 30 | Second beam column |
| 32 | Surface |
| 34 | Area |
| 36 | Electron beam spot |
| 38 | Imaging configuration |
| 40 | Erasing configuration |
| 42 | Arrow |
| 50 | Beam booster stage |
| 52 | Field lens |
| 54 | Electromagnetic aperture changer |
| 56 | Annular BSE detector |
| 58 | Annular SE detector |
| 60 | Electromagnetic lens |
| 62 | Electrostatic lens |
| 64 | Object |
| 66 | High voltage source |
| 68 | Gun |
| 70 | Units |
| 72 | Apertures |
| 74 | Lens |
| 76 | Electron beam |
| 78 | Opening |

What is claimed is:

1. A method for balancing charges on a surface of an object comprising integrated circuit patterns in a scanning electron microscope, the method comprising:
scanning an area on the surface of the object with a first electron beam with a first landing energy one or more times to generate a scanning electron microscopy image of the area from the amount of emitted electrons per dwell point, thereby accumulating charges on the surface of the object; and
subsequently scanning the area on the surface of the object with a second electron beam with a second landing energy one or more times such that the charges accumulated on the surface of the object are at least partially balanced.

2. The method of claim 1, wherein the first landing energy is selected to optimize the quality of the generated scanning electron microscopy image.

3. The method of claim 2, wherein the quality of the generated scanning electron microscopy image is measured by at least one image quality metric from the group comprising contrast, sharpness, distortion, signal to noise ratio, beam drift, magnification variation.

4. The method of claim 2, wherein the first landing energy and/or a beam current of the first electron beam and/or a scanning time per area of the first electron beam are selected according to at least one image quality metric.

5. The method of claim 4, wherein the at least one image quality metric is optimized.

6. The method of claim 1, wherein the first landing energy is selected to maximize the electron emission yield of the object.

7. The method of claim 1, wherein the first landing energy has an electron emission yield greater than 1 and the second landing energy has an electron emission yield smaller than 1, or wherein the first landing energy has an electron emission yield smaller than 1 and the second landing energy has an electron emission yield greater than 1.

8. The method of claim 1, wherein a beam current of the second electron beam and/or a scanning time per area of the second electron beam is selected according to a function of the first landing energy, a beam current of the first electron beam, a scanning time per area of the first electron beam and the second landing energy of the second electron beam.

9. The method of claim 1, wherein the scanning electron microscope comprises a beam column, and wherein the first electron beam and the second electron beam are both generated by said beam column.

10. The method of claim 1, wherein the area on the surface of the object corresponds to a scan line of the first electron beam.

11. The method of claim 1, wherein the area on the surface of the object is scanned with the second electron beam during the beam fly-back after scanning the area with the first electron beam.

12. The method of claim 1, wherein the area on the surface of the object is repeatedly scanned with the first electron beam and subsequently once with the second electron beam, wherein the second electron beam is adjusted to balance the accumulated charges of the repeated scans with the first electron beam.

13. The method of claim 1, wherein the area on the surface of the object is scanned once with the first electron beam and subsequently repeatedly with the second electron beam, wherein the second electron beam is adjusted to balance the accumulated charges of the scan with the first electron beam during the repeated scans with the second electron beam.

14. The method of claim 1, wherein the shape of an electron beam spot generated on the surface of the object by the first electron beam or by the second electron beam is adjusted to the first landing energy during scanning of the area on the surface of the object with the first electron beam, and the shape of the electron beam spot is not adjusted to the second landing energy during scanning of the area on the surface of the object with the second electron beam.

15. A scanning electron microscope for examination of an object comprising integrated circuit patterns, the scanning electron microscope comprising:
a first beam column configured to direct a first electron beam with a first landing energy towards an area on the surface of the object, thereby accumulating charges on the surface of the object;
a second beam column configured to direct a second electron beam with a second landing energy towards the area on the surface of the object such that the accumulated charges on the surface of the object are at least partially balanced; and
a detector configured to detect emitted electrons from the area on the surface of the object during the scanning of the area with the first electron beam.

16. A scanning electron microscope for examination of an object comprising integrated circuit patterns, the scanning electron microscope comprising:
a beam column configured to direct a first electron beam with a first landing energy towards an area on the surface of the object, thereby accumulating charges on the surface of the object, and to subsequently direct a second electron beam with a second landing energy towards the area on the surface of the object such that the accumulated charges on the surface of the object are at least partially balanced; and
a detector configured to detect emitted electrons from the area on the surface of the object during the scanning of the area with the first electron beam.

17. The scanning electron microscope of claim 16, wherein the beam column has a beam booster stage comprising a high voltage source and a combined electrostatic-electromagnetic lens, the high voltage source being configured for accelerating electrons in the first electron beam or in the second electron beam within the beam column, and the electrostatic-electromagnetic lens being configured for decelerating electrons in the first electron beam or in the second electron beam before leaving the beam column, and wherein the beam booster stage of the beam column is configured for controlling the first landing energy of the first electron beam and the second landing energy of the second electron beam.

18. The scanning electron microscope of claim 16, wherein the beam column includes units providing an electromagnetic field for selectively directing the first electron beam and the second electron beam through different apertures thereby defining the beam current of the first electron beam and the beam current of the second electron beam.

19. The scanning electron microscope of claim 15, configured to generate the first electron beam with a diameter smaller than 5 nm.

20. The scanning electron microscope of claim 15, further comprising a control unit for controlling the first electron beam and the second electron beam according to a method for balancing charges on the surface of the object, the method comprising:
scanning the area on the surface of the object with the first electron beam with the first landing energy one or more times to generate a scanning electron microscopy image of the area from the amount of emitted electrons per dwell point, thereby accumulating the charges on the surface of the object; and
subsequently scanning the area on the surface of the object with the second electron beam with the second landing energy one or more times such that the charges accumulated on the surface of the object are at least partially balanced.
